(19) United States
(12) Patent Application Publication
(10) Pub. No.: US 2010/0165589 A1
(43) Pub. Date: Jul. 1, 2010

(54) SIM CARD, SIM CARD HOLDER AND ELECTRONIC DEVICE WITH SAME

(75) Inventor: Ri Zhou, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); CHI MEI COMMUNICATION SYSTEMS, INC., Tu-Cheng City (TW)

(21) Appl. No.: 12/512,395

(22) Filed: Jul. 30, 2009

(30) Foreign Application Priority Data
Dec. 25, 2008 (CN) 200810306537.5

(51) Int. Cl. H05K 5/00

(52) U.S. Cl. 361/759; 361/783

(57) ABSTRACT

A. SIM card includes a base body, two integrated circuits mounted on the base body, an electrical connector electrically connected to each of the two integrated circuits respectively. A SIM card holder for the SIM card includes a bracket defining a cavity to receive the SIM card, and a terminal connected to each of the electrical connectors respectively. The SIM card and the SIM card holder occupy little space and can be easily assembled and detached.

### BACKGROUND

1. Technical Field

The present disclosure relates generally to a SIM card, a SIM card holder, and an electronic device with the SIM card and the SIM card holder.

2. Description of Related Art

A subscriber identity module (SIM) card generally carries an integrated circuit (IC). The SIM card may be installed or otherwise inserted into a mobile communication device (e.g. cellular telephone) which contains subscriber related data. For example, the SIM card is used in the cellular telephone that conforms to the global system for mobile communications (GSM) standard, the third generation code division multiple access (CDMA) standard, or other products, and may include many personal communication services applications. GSM cellular telephones, or other SIM based devices are typically not fully functional without the SIM card being inserted. The SIM card includes a body, an IC having a processor and a memory. The memory stores algorithms and contains data that identifies the caller as being a legitimate user of the mobile network. The processor encrypts voice and data transmissions.

Typically, the SIM card is maintained within a cellular telephone in a card holder. However, with the increasing amount of features and capabilities provided by the cellular telephone, multiple cards are oftentimes required to provide appropriate functionality and user flexibility. A commonly used multiple SIM card system employs a housing structure where the SIM cards are placed next to each other (e.g. side-by-side) on the circuit board of the cellular telephone. However, using multiple SIM cards this way may increase the overall size of the cellular telephone. With the ever increasing importance of scaling down, or reducing the size of cellular telephones, side-by-side placement of the SIM cards impedes any size reduction efforts.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views, and all the views are schematic.

FIG. 1 is a plan view of one embodiment of a mobile phone with a SIM card and a SIM card holder therein.

FIG. 2 is an isometric view of the SIM card of FIG. 1.

FIG. 3 is an isometric of the SIM card holder of FIG. 1.

FIG. 4 is similar to FIG. 3, but viewed from another aspect.

FIG. 5 is a circuit diagram showing the SIM card holder electrically connected the SIM card and a connecting circuit.

### DETAILED DESCRIPTION

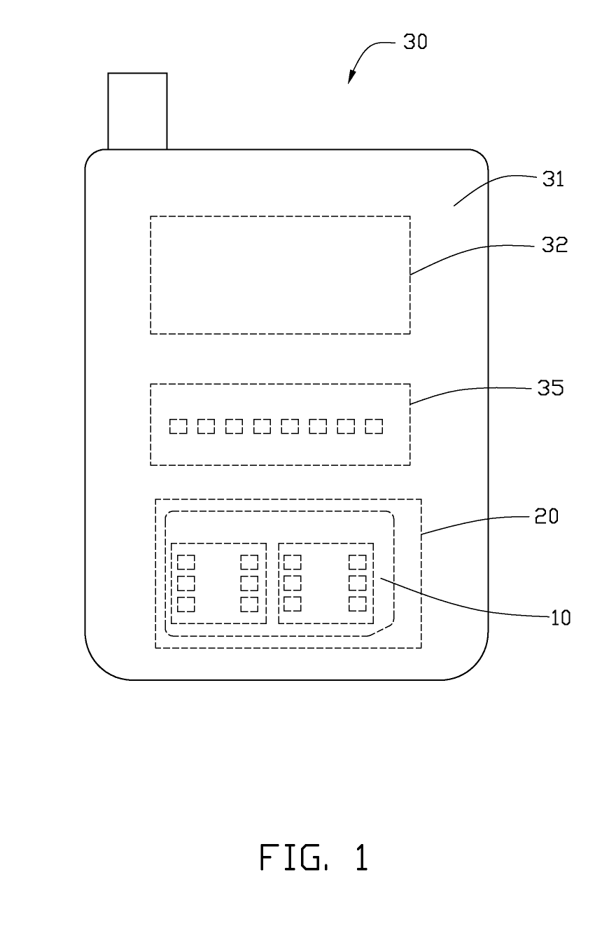

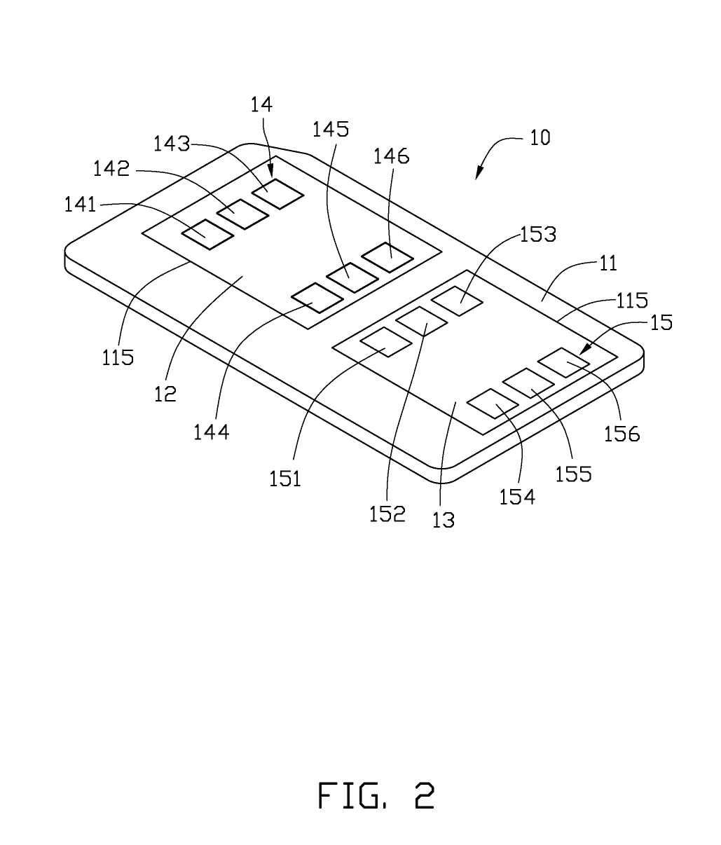

Referring to FIGS. 1 and 2, an embodiment of a mobile phone 30 includes a main body 31 and a main circuit board 32 received in the main body 31, a connecting circuit 35, a SIM card 10, and a SIM card holder 20 received in the main body 31.

An embodiment of a SIM card 10 includes a base body 11, a first IC 12, a second IC 13, a first electrical connector 14 electrically connected to the first IC 12, and a second electrical connector 15 electrically connected to the second IC 13.

The base body 11 is a substantially plastic sheet. A surface of the base body 11 defines two areas 115 to receive the first and second ICs 12,13 respectively. The base body 11 may be sufficiently rigid and durable to resist deteriorative environments and protect the SIM card 10 from being deformed. The materials of the base body 11 may be selected from acrylonitrile butadiene styrene (ABS) and polyvinylchloride (PVC).

The first and second ICs 11,12 are both used to store algorithms, encrypt voice and data transmissions, and also contain data that identify the caller as being a legitimate user of the mobile network, thus one SIM card 10 is capable of providing all functions commonly supplied by two cards each with only one IC therein.

The first electrical connector 14 includes a supply voltage (VCC) contact 141, a reset (RST) contact 142, a clock signal (CLK) contact 143, a ground (GND) contact 144, a programming voltage (VPP) contact 145 and a data input/output (I/O) contact 146. The second electrical connector 15 is similar to the first electrical connector 14, and also includes a VCC contact 151, a RST contact 152, a CLK contact 153, a GND contact 154, a VPP contact 155 and an I/O contact 156. The contacts of the first and second electrical connectors 14,15 are electrically connected to the pins on the first and second ICs 12,13 respectively. Since the first and second ICs 12,13 are integrated in one base body 11 and placed side-by-side, the SIM card 10 is capable of functioning as two independently commonly used SIM cards which each have only one IC therein. In addition, the distance between the second ICs 12,13 can be reduced, and then the amount volume occupied by the SIM card 10 is reduced correspondingly. Thereby, the cost may be cut down due to the amount of material used to form the base body 11 being reduced. Furthermore, the first and second ICs 12,13 can be used in different networks or configured with two phone numbers in one network.

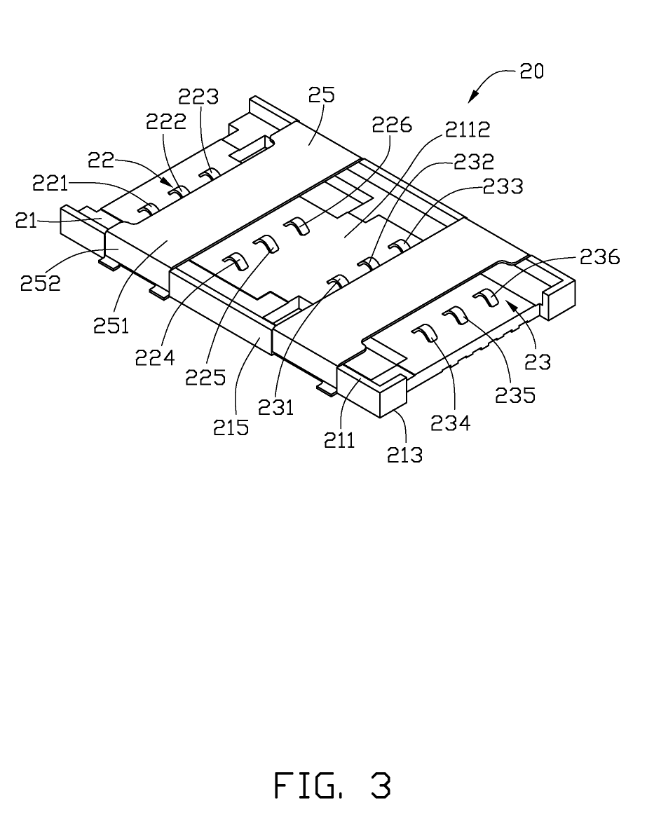

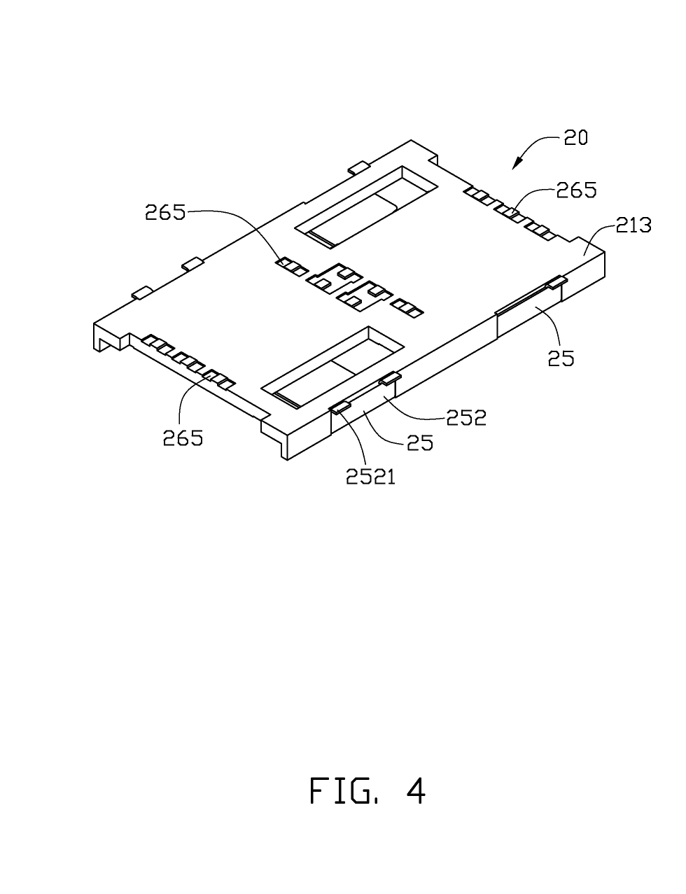

Referring to FIGS. 3 and 4, an embodiment of a SIM card holder 20 is disclosed. The SIM card holder 20 is used to receive the SIM card 10 and electrically connect the SIM card 10 and the connecting circuit 35. The SIM card holder 20 includes a bracket 21, a first terminal 22, a second terminal 23, and two fixing assemblies 25.

The bracket 21 is substantially rectangular, and includes a top surface 211, a bottom surface 213 opposite to the top surface 211, and a side surface 215 connecting the top surface 211 and the bottom surface 213. The top surface 211 defines a cavity 2112 to receive the SIM card 10. The bracket 21 may be made of plastic by insert-molding.

The first terminal 22 is used to electrically connect the first IC 12, and the second terminal 23 is used to electrically connect the second IC 13. The first terminal 22 includes a VCC part 221, a RST part 222, a CLK part 223, a GND part 224, a VPP part 225, and an I/O part 226. The second terminal 23 includes a VCC part 231, a RST part 232, a CLK part 233, a GND part 234, a VPP part 235, and an I/O part 236. In the illustrated embodiment, each of the first and second terminals 22,23 includes an elastic arcuate sheet connected to the SIM card 10 and a pin 265 formed on the bottom surface 213 corresponding to the arcuate sheet.

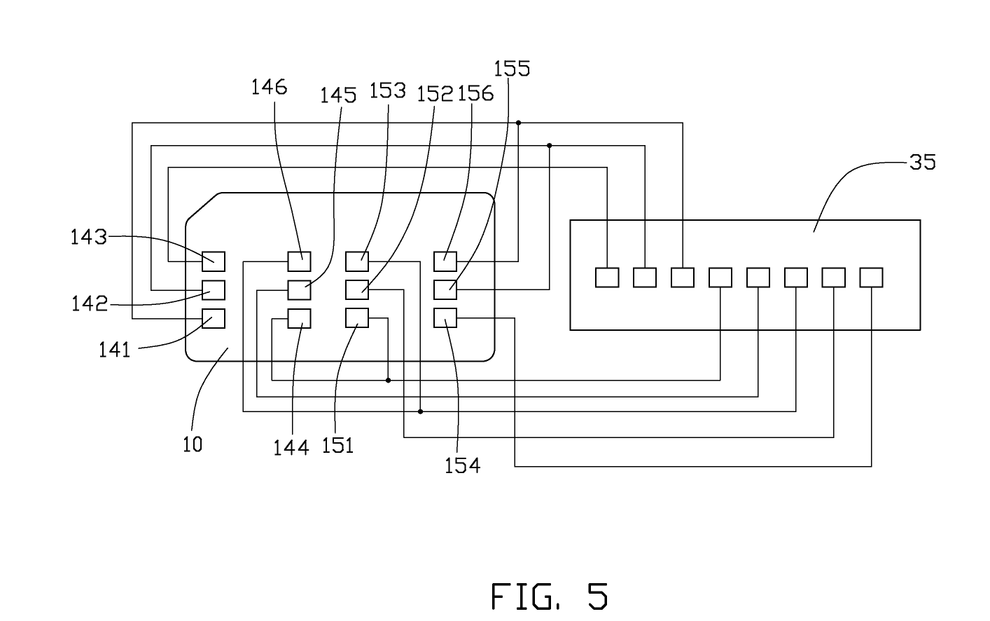

FIG. 5 is a schematic circuit diagram showing the SIM card holder 20 electrically connecting the SIM card 10 and the connecting circuit 35. Since the RST contacts 221,231, the CLK contacts 223,233, the GND contacts 224,234 and the I/O contacts can be coupled with each other and then connected to the connecting circuit 35 correspondingly, the number of contacts can be reduced to eight. Thereby the circuit is simplified, and the volume the SIM card holder 20 occupies reduced. In addition, this has the effect of substantially increasing the amount of available area for other circuits.

The fixing assembly 25 includes a base sheet 251, two sidewalls 252 perpendicularly extending from opposite sides of the base sheet 251, and a connecting portion 2521 formed on the end of the sidewall 252. The base sheet 251 elastically resists on the SIM card 10, and the two sidewalls 252 are fixed to the two sides 215 of the bracket 21, such that the SIM card 10 is securely fixed in the cavity 2112. The connecting portion 2521 is used to connect the SIM card holder 20 to the main body 31.

In assembly, the two sidewalls 252 of the fixing assembly 25 are fixed to the two sides of the bracket 21 correspondingly, the SIM card 10 is inserted into the cavity 2112, at the same time, the base sheet 251 resists on the SIM card 10 elastically from the top. By the elastic force provided by the base sheet 251, the SIM card 10 resists on the contacts of the first and second terminals 22,23, and then the first electrical connector 14 is electrically connected to the first terminal 22, and the second electrical connector 15 is connected to the second terminal 23. To detach the SIM card 10 from the SIM card holder 20, just draw the SIM card 10 from the cavity 2112.

In use, users can select one of the first IC 12 and second IC 13 to work by operating the menu on the display and a selecting signal is produced correspondingly. The main circuit board 32 connects the selected IC in response to the selecting signal. Consequently, users can switch between two phone numbers corresponding to the first and second ICs 12,13 to adapt to different users or different regions.

The connecting circuit 35 includes a switch (not shown) used to switch between the first IC 12 and the second IC 13. It can be understood that, the connecting circuit 35 also can use a chip select circuit to produce a selecting signal to select either the first IC 12 or the second IC 13.

It should be noted that the SIM card 10 may include three or more ICs integrated in the base body 11, and the SIM card holder 20 providing terminals electrically connected to the ICs correspondingly.

Finally, while various embodiments have been described and illustrated, the disclosure is not to be construed as being limited thereto. Various modifications can be made to the embodiments by those skilled in the art without departing from the true spirit and scope of the disclosure as defined by the appended claims.

What is claimed is:

1. A SIM card, comprising:
a base body;
at least two integrated circuits mounted on the base body;
an electrical connector electrically connected to each of the at least two integrated circuits respectively.

2. The SIM card of claim 1, wherein the SIM card comprises two integrated circuits and two electrical connectors, each electrical connector connected to one of the two integrated circuits respectively.

3. The SIM card of claim 2, wherein each electrical connector comprises a supply voltage contact, a reset contact, a clock signal contact, a ground contact, a programming voltage contact and a data input/output contact.

4. The SIM card of claim 3, wherein the two integrated circuits are used in different mobile networks.

5. The SIM card of claim 2, wherein the base body is a substantially plastic sheet and comprises a surface defining two areas to receive the two integrated circuits respectively.

6. The SIM card of claim 5, wherein the materials of the base body is selected from acrylonitrile butadiene styrene and polyvinylchloride.

7. A SIM card holder for a SIM card having a base body, at least two integrated circuits mounted on the base body, and an electrical connector electrically connected to each of the at least two integrated circuits respectively, the SIM card holder comprising:
a bracket defining a cavity to receive the SIM card;
a terminal connected to each of the electrical connectors respectively; and at least one fixing assembly to fix the SIM card to the bracket.

8. The SIM card holder of claim 7, wherein each terminal comprises a supply voltage part, a reset part, a clock signal part, a ground part, a programming voltage part and a data input/output part.

9. The SIM card holder of claim 7, wherein each fixing assembly comprises a base sheet, two sidewalls substantially perpendicularly extending from opposite sides of the base sheet, and a connecting portion formed on the end of the sidewall, the SIM card is fixed in the cavity by the base sheet elastically resisting on the SIM card and the two sidewalls being fixed to the two sides of the base body.

10. The SIM card holder of claim 7, wherein the bracket is plastic and formed by insert-molding.

11. The SIM card holder of claim 7, wherein each terminal comprises a plurality of elastic arcuate sheets connected to the SIM card and pins formed on a bottom surface of the bracket corresponding to the arcuate sheets.

12. An electronic device comprising:
a main body;
a main circuit board received in the main body;
a SIM card comprising a base body, at least two integrated circuits mounted on the base body, and an electrical connector electrically connected to each of the at least two integrated circuits respectively;
a SIM card holder comprising a bracket defining a cavity to receive the SIM card, a terminal connected to each of the at least electrical connectors respectively, and at least one fixing assembly to fix the SIM card to the bracket; and
a connecting circuit connecting the SIM card to the main circuit board.

13. The electronic device of claim 12, wherein each fixing assembly comprises a base sheet, two sidewalls substantially perpendicularly extending from opposite sides of the base sheet, and a connecting portion formed on the end of the sidewall, the SIM card is fixed in the cavity by the base sheet elastically resisting on the SIM card and the two sidewalls being fixed to the two sides of the base body.

14. The electronic device of claim 12, wherein the bracket is plastic and formed by insert-molding.

15. The electronic device of claim 12, wherein each terminal comprises a plurality of elastic arcuate sheets connected to the SIM card and pins formed on a bottom surface of the bracket corresponding to the arcuate sheets.
